(19) United States
(12) Patent Application Publication
(10) Pub. No.: US 2018/0307345 A1
(43) Pub. Date: Oct. 25, 2018

(54) SYSTEM FOR DETECTING INPUTS INTO A COMPUTING DEVICE

(71) Applicant: Tactus Technology, Inc., Hayward, CA (US)

(72) Inventor: Micah Yairi, Hayward, CA (US)

(21) Appl. No.: 15/799,976

(22) Filed: Oct. 31, 2017

Related U.S. Application Data
(60) Provisional application No. 62/415,358, filed on Oct. 31, 2016.

(51) Int. Cl. G06F 3/044; G06F 3/041; H03K 17/975; H03K 17/96

(52) U.S. Cl. CPC G06F 3/044; H03K 17/962; H03K 17/975; G06F 3/0414

(57) ABSTRACT

One variation of a system for detecting inputs into a computing device includes an elastic film: configured to install over a capacitive touch sensor including a rigid substrate; characterized by a dielectric constant greater than 3.0; defining a touch sensor surface across a nominal plane offset from the rigid substrate; configured to locally deform inwardly from the nominal plane toward the rigid substrate responsive to an input applied to the touch sensor surface; configured to reduce strength of an electric field projected by the capacitance touch sensor across the nominal plane; configured to decrease capacitance between local pairs of electrodes in the capacitive touch sensor as a function of local depression of the touch sensor surface toward the rigid substrate proximal the particular sense electrode; and configured to locally return the touch sensor surface to the nominal plane responsive to release of the local input from the touch sensor surface.

### CROSS-REFERENCE TO RELATED APPLICATIONS

This Application claims the benefit of U.S. Provisional Application No. 62/415,358, filed on 31 Oct. 2016, which is incorporated in its entirety by this reference.

### TECHNICAL FIELD

This invention relates generally to the field of capacitive touch sensors and more specifically to a new and useful system for detecting inputs into a computing device in the field of capacitive touch sensors.

### BRIEF DESCRIPTION OF THE FIGURES

FIG. 1 is a schematic representation of a system;

FIG. 2 is a flowchart representation of a method executed by one variation of the system; and

FIG. 3 is a schematic representation of one variation of the system.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. System

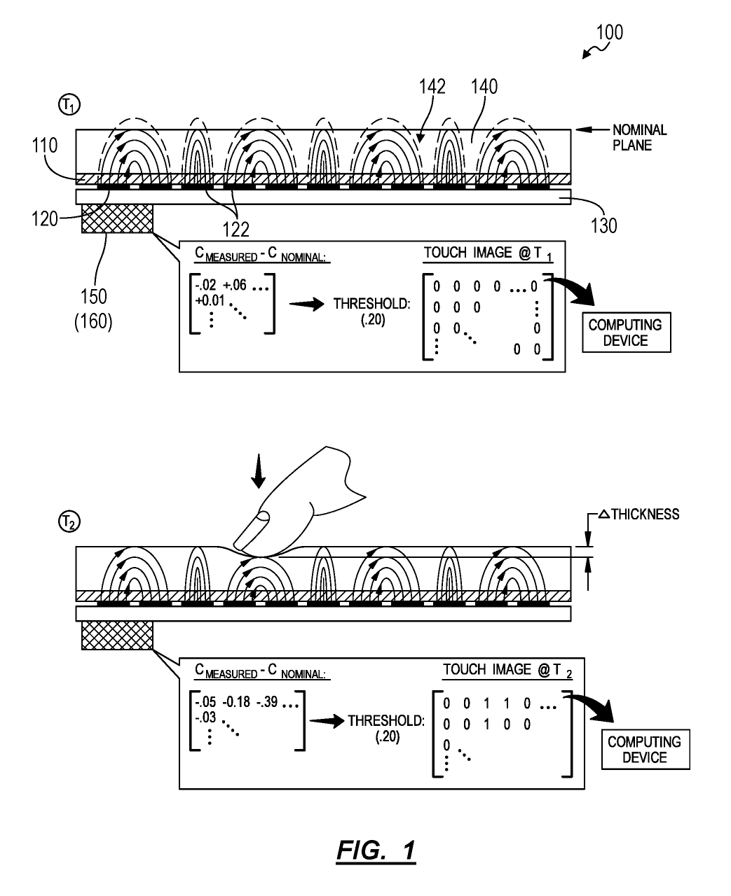

As shown in FIG. 1, a system 100 for detecting inputs into a computing device includes: a rigid substrate 110; a capacitive touch sensor 120 arranged across the rigid substrate 110 and including an array of electrodes 122; and an elastic layer 140 arranged across the rigid substrate 110, defining a touch sensor surface 142 across a nominal plane offset above the rigid substrate 110, and configured to locally deform inwardly toward the rigid substrate 110 responsive to a local input applied to the touch sensor surface 142. The system 100 also includes a controller 150 configured to: apply electrical voltage to electrodes 122 in the capacitive touch sensor 120 to induce an electric field projected through the elastic layer 140; read capacitance values from electrodes 122 in the capacitive touch sensor 120; access a threshold capacitance value perturbation corresponding to presence of a conductive object below the nominal plane; and detect an input at a particular location on the touch sensor surface 142 in response to a local disturbance in capacitance value, read from a particular electrode in the set of electrodes 122 in the capacitive touch sensor 120 proximal the particular location, that exceeds the threshold capacitance value perturbation.

One variation of the system 100 includes an elastic film: configured to install over a capacitive touch sensor 120 including a rigid substrate 110; characterized by a dielectric constant greater than 3.0; defining a touch sensor surface 142 across a nominal plane offset from the rigid substrate 110; configured to locally deform inwardly from the nominal plane toward the rigid substrate 110 responsive to a local input applied to the touch sensor surface 142; configured to reduce strength of an electric field projected by the capacitance touch sensor across the nominal plane; configured to decrease capacitance between local pairs of electrodes 122 in the capacitive touch sensor 120 as a function of local depression of the touch sensor surface 142 toward the rigid substrate 110 proximal the particular sense electrode; and configured to locally return the touch sensor surface 142 to the nominal plane responsive to release of the local input from the touch sensor surface 142. This variation of the system 100 can further include a software program 160 executable by the capacitance touch sensor to detect an input at a particular location on the touch sensor surface 142 in response to a local disturbance in capacitance read from a particular electrode in the capacitive touch sensor 120 proximal the particular location.

### 2. Applications

The system 100 includes an elastic layer 140 (e.g., an elastomeric film) configured to transiently install over a capacitive touch sensor 120 or to be intransiently integrated over a capacitive touch sensor 120. The elastic layer 140 defines a touch sensor surface 142 opposite the capacitive touch sensor 120, compresses locally against the capacitive touch sensor 120 (e.g., against a rigid substrate 110 supporting the capacitive touch sensor 120) when a local force is applied to the touch sensor surface 142, and returns to a nominal thickness when such local force is removed from the touch sensor surface 142. The elastic layer 140 is also characterized by a dielectric constant greater than air (i.e., greater than 1.0) and therefore increases capacitance between paired electrodes 122 in the capacitive touch sensor 120 as a function of the dielectric constant and the thickness of the elastic layer 140 proximal these paired electrodes 122. In particular, in the absence of local forces applied to the touch sensor surface 142 (i.e., when the elastic layer 140 is in a nominal state), the elastic layer 140 defines a substantially uniform thickness and therefore yields a substantially uniform increase in capacitance between paired electrodes 122 in the capacitive touch sensor 120. However, when an object is depressed against a local region of the touch sensor surface 142, the thickness of the elastic layer 140 at this local region decreases, thereby decreasing capacitance between electrode pairs 122 in the capacitive touch sensor 120 proximal this local region. A controller 150 connected to the capacitive touch sensor 120 may detect this change in capacitance between these electrode pairs 122 and register an input at this local region of the touch sensor surface 142 accordingly.

Therefore, the elastic layer 140 can function to interact with electric fields projected out of a capacitive touch sensor 120 and thus measurably affect capacitance of electrode pairs 122 in capacitive touch sensor 120 as a function of local thickness of the elastic layer 140. In particular, a force applied to a local region of the elastic layer 140 by a non-conductive object (e.g., a non-conductive stylus) may compress the elastic layer 140 and thus yield a measurable change in capacitance between adjacent electrode pairs 122 in the touch sensor surface 142. The controller 150 can thus register an input at this local region over the capacitive touch sensor 120 even though the object in contact with the touch sensor surface 142 is non-conductive and therefore does not interact (or only minimally interacts) with electric fields projected by the capacitive touch sensor 120, as shown in FIGS. 1, 2, and 3.

Similarly, a force applied to a local region of the elastic layer 140 by a conductive object (e.g., a finger or conductive stylus) may compress the elastic layer 140, yield a measurable change in capacitances between adjacent electrode pairs 122 in the touch sensor surface 142, and bleed electrical charge from nearby electrode pairs 122 in the capacitive touch sensor 120. In particular, as the conductive object contacts the local region of the touch sensor surface 142 with greater force, the elastic layer 140 compresses locally, the absolute distance between the conductive object and nearby electrode pairs 122 decreases, the conductive object absorbs electrical charge from these nearby electrode pairs 122 at an increasing rate, and the reduction in thickness of the elastic layer 140 at the local region yields reduction in capacitances between these nearby electrode pairs 122. As capacitances between these nearby electrode pairs 122 decreases and as the conductive object absorbs charge from these electrode pairs 122 responsive to application of the object onto the touch sensor surface 142, discharge times of these electrode pairs 122 (i.e., time to discharge from a high voltage to a low voltage) may decrease dramatically. By monitoring discharge times of electrode pairs 122 across the capacitive touch sensor 120, the controller 150 can thus detect presence of the conductive object in constant with the touch sensor surface 142 with a high degree of confidence.

Therefore, the elastic layer 140 can be compressible, can be applied or integrated over a capacitive touch sensor 120, and can interact with electric fields output by electrode pairs 122 in the capacitive touch sensor 120 as a function of thickness, thereby enabling a controller 150 connected to the capacitive touch sensor 120 to detect presence of an object in contact with the elastic layer 140, even if the object is non-conductive.

The elastic layer 140 is described below as integrated (e.g., intransiently installed) over a rigid substrate 110, wherein the rigid substrate 110 also functions to support the capacitive touch sensor 120 including an array of electrodes 122 and connected to a controller 150. For example, the elastic layer 140, rigid substrate 110, capacitive touch sensor 120, and controller 150 can form a user interface system 100 integrated into a smartphone, tablet, touchpad, laptop computer, or other computing device.

Alternatively, the elastic layer 140 can define a discrete film configured to transiently (i.e., removably) install over a capacitive touch sensor 120 in an existing computing device. The elastic layer 140 can also be paired with a software program 160 executable by a controller 150 connected to the capacitive touch sensor 120; the elastic layer 140 and the software program 160 can thus enable the controller 150—and the computing device generally—to detect inputs over the capacitive touch sensor 120 even by non-conductive objects.

### 3. Substrate and Capacitive Touch Sensor

The system 100 includes: a rigid substrate 110; and a capacitive touch sensor 120 arranged across the rigid substrate 110 and including an array of electrodes 122. Generally, the rigid substrate 110 supports the capacitive touch sensor 120 and the elastic layer 140. The capacitive touch sensor 120 includes electrodes 122 that capacitively couple and project electric fields through the elastic layer 140 when electrically charged; these electric fields are affected by the elastic layer 140 and objects nearby, and the controller 150 (described below) interprets detected perturbations in these electric fields as inputs in discrete locations over the capacitive touch sensor 120.

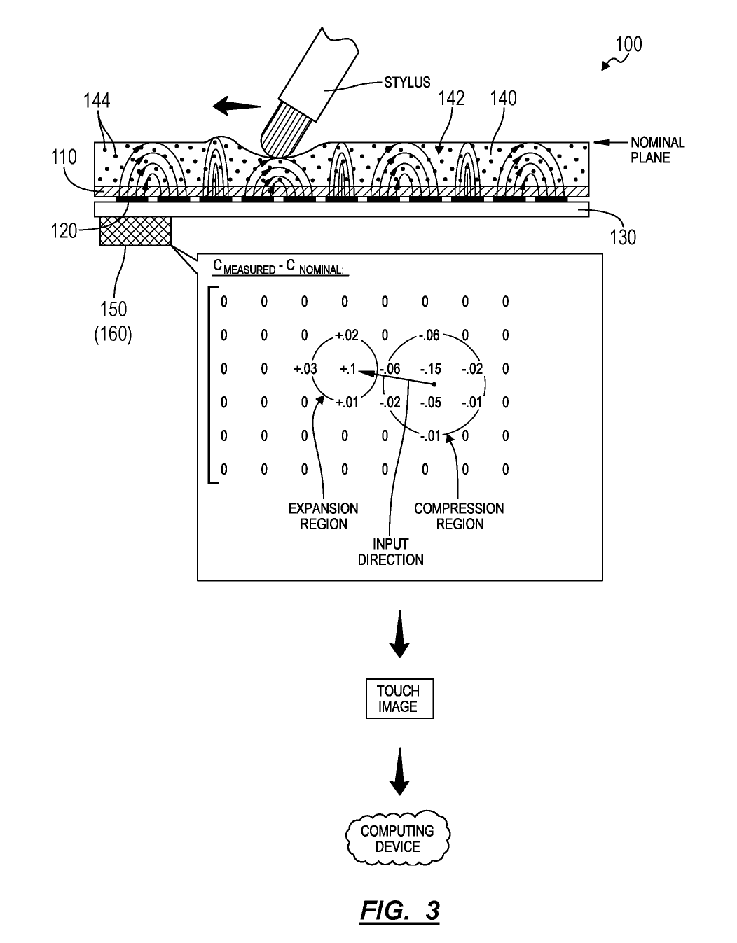

In one implementation shown in FIGS. 1 and 3, the rigid substrate 110 and the capacitive touch sensor 120 cooperate to define a touch-sensitive display 130 (i.e., a “touchscreen”). For example, the rigid substrate 110 can include a transparent silicate (i.e., glass) panel over a digital liquid-crystal display, and the capacitive touch sensor 120 can include a translucent array of electrodes 122, such as indium tin oxide patterned across the silicate panel to form rows of optical sensor drive electrodes 122 and columns of sense electrodes 122. Alternatively, the rigid substrate 110 can define an opaque structure, such as a rigid non-conductive polymer panel; and electrodes 122 of the capacitive touch sensor 120 can be patterned across one or both sides of the rigid substrate 110.

The capacitive touch sensor 120 is described herein as including electrodes 122 arranged in a projected mutual capacitance configuration. However, the capacitive touch sensor 120 can alternatively include electrodes 122 arranged in a projected self capacitance configuration or in a surface capacitance configuration.

### 4. Elastic Layer

As shown in FIGS. 1 and 3, the elastic layer 140 is arranged across the rigid substrate 110, defines a touch sensor surface 142 across a nominal plane offset above the rigid substrate 110, and is configured to locally deform inwardly toward the rigid substrate 110 responsive to a local input applied to the touch sensor surface 142. Generally, the elastic layer 140 defines a film, cover layer, or similar structure characterized by a dielectric constant (or a conductivity, as described below) different from air and thus interacts with electric fields projected by electrodes 122 in the capacitive touch sensor 120.

In one variation, the elastic layer 140: is configured to install over a capacitive touch sensor 120 including a rigid substrate 110; is characterized by a dielectric constant greater than 3.0; defines a touch sensor surface 142 across a nominal plane offset from the rigid substrate 110; is configured to locally deform inwardly from the nominal plane toward the rigid substrate 110 responsive to a local input applied to the touch sensor surface 142; is configured to reduce strength of an electric field projected by the capacitance touch sensor across the nominal plane; is configured to decrease capacitance between local pairs of electrodes 122 in the capacitive touch sensor 120 as a function of local depression of the touch sensor surface 142 toward the rigid substrate 110 proximal the particular sense electrode; and is configured to locally return the touch sensor surface 142 to the nominal plane responsive to release of the local input from the touch sensor surface 142.

In one implementation, the elastic layer 140 is characterized by a dielectric constant greater than air, such as greater than 2.0, greater than 3.0, or greater than 20.0 at room temperature. Because the elastic layer 140 is arranged over the capacitive touch sensor 120, the elastic layer 140 inhibits electric fields between paired electrodes 122 in the capacitive touch sensor 120 below the elastic layer 140 and increases capacitances between these electrode pairs 122 when driven to a non-zero voltage by the controller 150. By increasing capacitance between these two electrodes 122, the elastic layer 140 can yield slower charge and discharge rates for these electrode pairs 122 in a nominal state.

Furthermore, the elastic layer 140 can define a substantially uniform thickness and substantially uniform dielectric constant across its width and length and therefore yield a substantially uniform increase in capacitance of electrode pairs 122 across the capacitive touch sensor 120 in a nominal state (i.e., when no form is applied to the elastic layer 140 to compress or otherwise alter a local thickness of the elastic layer 140). In particular, the elastic layer 140 can define a touch sensor surface 142 spanning a nominal plane above the capacitive touch sensor 120 and the rigid substrate 110. For example, the rigid substrate 110 can define a planar structure, the capacitive touch sensor 120 can include electrodes 122 patterned across the planar structure, and the elastic layer 140 can define the touch sensor surface 142 across a nominal plane offset above and parallel to the planar structure in the absence of a local force applied to the touch sensor surface 142.

However, the elastic layer 140 is also compressible. In particular, the elastic layer 140 can locally deform inwardly toward the rigid substrate 110 when a force is applied to a local region of the touch sensor surface 142. For example, the elastic layer 140 can include an elastomeric film, such as a sheet of one or more layers of silicone, urethane, and/or neoprene, etc. of a total nominal thickness (e.g., one-tenth of a millimeter, one millimeter, two millimeters). In the implementation described above in which the rigid substrate 110 and the capacitive touch sensor 120 form a touchscreen, the elastic layer 140 can define a translucent (or transparent) polymer film permanently assembled or transiently applied over the touchscreen. The elastic layer 140 can be configured to compress by a fraction of its thickness, such as by 50% of its nominal thickness when a force of one pound per square inch is applied normal to the touch sensor surface 142. In particular, the elastic layer 140 can compress as a function of pressure (i.e., force per unit area) applied to the touch sensor surface 142 such that the effect of the elastic layer 140 on the electric field output by the capacitive touch sensor 120—and therefore on capacitances between electrode pairs 122 in the capacitive touch sensor 120—varies as a function of local compression of the elastic layer 140 (e.g., as a function of force applied to the elastic layer 140). For example, the elastic layer 140 can define a touch sensor surface 142 across the nominal plane offset above the planar structure by a uniform offset distance, and the touch sensor surface 142 can locally deform below the nominal plane by a distance proportional to a magnitude of a local force applied to the touch sensor surface 142.

The elastic layer 140 can be characterized by a dielectric constant that differs significantly from the dielectric constant of air; in the nominal condition (i.e., when no force is applied to a local region of the elastic layer 140), the elastic layer 140 can thus yield an increase in capacitance between nearby electrodes 122 in the capacitive touch sensor 120. However, when a local region of the elastic layer 140 is compressed by a force applied locally to the touch sensor surface 142, this material in the elastic layer 140 at this local region is compressed and/or displaced laterally away from the location of the applied force, thereby reducing the effective thickness of the elastic layer 140, bringing air—characterized by a lesser dielectric constant—closer to the capacitive touch sensor 120, and reducing capacitance between nearby pairs of electrodes 122 in the capacitive touch sensor 120. (The elastic layer 140 can exhibit an even greater dielectric constant in order to further exacerbate this effect, thereby yielding even greater change in capacitance of electrode pairs 122 in the capacitive touch sensor 120 when a local force is applied to the touch sensor surface 142 nearby, thereby heightening sensitivity of the system 100 to inputs on the touch sensor surface 142 and improving detection of such inputs by the controller 150.)

Therefore, in one implementation described above, the capacitive touch sensor 120 can include an array of drive electrodes 122 (e.g., rows of electrodes 122) and an array of sense electrodes 122 (e.g., columns of electrodes 122) configured to capacitively couple to adjacent sense electrodes 122 in the array of drive electrodes 122. In this implementation, the elastic layer 140 can: reduce strength of the electric field between the array of sense electrodes 122 and the array of drive electrodes 122 across the nominal plane in the nominal condition; and can decrease capacitance between a particular sense electrode in the array of sense electrodes 122 and an adjacent drive electrode in the array of drive electrodes 122 as a function of local depression of the touch sensor surface 142 toward the rigid substrate 110 proximal the particular sense electrode.

The elastic layer 140 can alternatively be relatively thick, such as nominally three or more millimeters thick, in order to buffer an electric field projected by the capacitive touch sensor 120 from extending beyond the touch sensor surface 142 with more than a threshold power. In particular, by defining a relatively large nominal thickness (and/or exhibiting a relatively high dielectric constant), the elastic layer 140 can inhibit electric fields projected by electrodes 122 in the capacitive touch sensor 120 from extending outwardly beyond the touch sensor surface 142 with significant power. By reducing electric field power beyond the touch sensor surface 142, the elastic layer 140 can thus reduce sensitivity of the system 100 to objects present near but not in contact with or not substantively depressing the touch sensor surface 142, thereby enabling a user to hover a finger, stylus, or other object over the touch sensor surface 142 or gently rest such an object on the touch sensor surface 142 without registering an input into the system 100. However, the relatively large nominal thickness of the elastic layer 140 may enable local regions of the elastic layer 140 to compress toward the rigid substrate 110 over a relatively large distance (e.g., 1.5 millimeters) as objects are applied to the touch sensor surface 142 with greater force. Given the dielectric constant of the elastic layer 140—which differs (significantly) from the dielectric constant of air—local compression of the elastic layer 140 in the presence of an applied force may yield a substantive, measurable change in capacitance of electrode pairs 122 nearby. The controller 150 can thus detect this local change in capacitance between these electrode pairs 122 and register an input at this location on the touch sensor surface 142 accordingly. Therefore, the elastic layer 140 can define a thickness and can be characterized by a dielectric constant that reduces sensitivity—of capacitance between electrode pairs 122 in the capacitive touch sensor 120—to objects near but not depressing the touch sensor surface 142. This greater thickness of the elastic layer 140 can also yield capacitance value changes between more electrode pairs 122 near an input on the touch sensor surface, thereby enabling the controller 150 to collect more touch information around this input and calculate the center and/or area of the input with greater resolution and accuracy during a scan cycle.

Additionally or alternatively, the elastic layer 140 can function to offset (or “buffer”) a conductive object (e.g., a finger, a conductive stylus) in contact with the touch sensor surface 142 from the capacitive touch sensor 120. By buffering the conductive object from the capacitive touch sensor 120, the elastic layer 140 can limit a rate of electrons bleeding from charged electrodes 122 in the capacitive touch sensor 120 to the conductive object, thereby limiting local perturbation in the capacitance value (e.g., charge time, discharge time) of nearby pairs of electrodes 122 in the capacitive touch sensor 120, thereby reducing sensitivity of the system 100 to the conductive object when the conductive object is near or just touching the touch sensor surface 142. However, as the conductive object is depressed into the elastic layer 140 with greater force, the elastic layer 140 can compress or deform locally, and the conductive object can move closer to the capacitive touch sensor 120, thereby increasing a rate at which charge moves from nearby charged electrodes 122 in the capacitive touch sensor 120 to the conductive object, thus increasing magnitude of perturbation of capacitance value of these nearby electrode pairs 122. For example, the resulting decrease in local thickness of the elastic layer 140 at the location of the conductive object can reduce capacitances between nearby electrode pairs 122, which an decrease discharge time for these electrode pairs 122 relative to other electrode pairs 122 in the capacitive touch sensor 120; furthermore, increased rate of charge bleed from these nearby electrode pairs 122 to the conductive object can further decrease discharge time; the effect of dramatic reducing in discharge time of these select electrode pairs 122 can thus be detected by the controller 150 and registered as an input at the corresponding location on the touch sensor surface 142 with a relatively high degree of confidence.

### 5. Controller

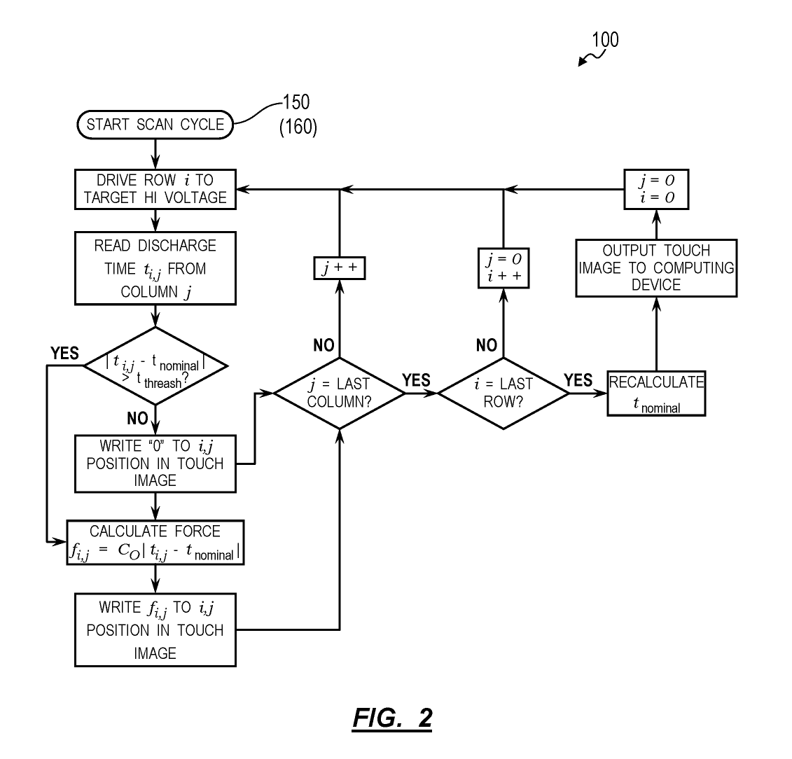

In the variation of the system 100 that includes a controller 150, the controller 150 is configured to: apply electrical voltage to electrodes 122 in the capacitive touch sensor 120 to induce an electric field projected through the elastic layer 140; read capacitance values (e.g., capacitance, discharge time, and/or charge time) from electrodes 122 in the capacitive touch sensor 120; access a threshold capacitance value perturbation corresponding to presence of a conductive object below the nominal plane; and detect an input at a particular location on the touch sensor surface 142 in response to a local disturbance in capacitance value, read from a particular electrode in the set of electrodes 122 in the capacitive touch sensor 120 proximal the particular location, that exceeds the threshold capacitance value perturbation. Generally, the elastic layer 140 functions to modify electric fields projected through the elastic layer 140—by electrode pairs 122 in the capacitive touch sensor 120 when charged—as a function of thickness of the elastic layer 140 (e.g., as a function of forces or pressures applied to local regions of the touch sensor surface 142), as described above; and the controller 150 functions to both charge these electrode pairs 122, such as sequentially during a scan cycle, and to detect variations in capacitance value of these electrode pairs 122 resulting from changes in local thickness of the elastic layer 140, as shown in FIGS. 1 and 3. The controller 150 can then interpret such variations in capacitance value at specific electrode pairs 122 as inputs on adjacent regions of the touch sensor surface 142, such as if these variations in capacitance value exceed a preset or calculated threshold perturbation value, as shown in FIG. 2.

In the implementation described above in which the capacitive touch sensor 120 defines a projected mutual capacitance capacitive touch sensor 120 including multiple rows of drive electrodes 122 and multiple columns of sense electrodes 122, the controller 150 can be connected to each row and column of electrodes 122. For example, during a single scan cycle, the controller 150 can: drive a first row of drive electrodes 122; sequentially read capacitance values (e.g., capacitance, charge time, and/or discharge time, etc.) from each column of sense electrodes 122; store these capacitance values in corresponding positions in a first row in a scan image (e.g., a 2×2 matrix with one (x,y) position per electrode pair in the capacitive touch sensor 120); and repeat this process for each other row of drive electrodes 122 in the capacitive touch sensor 120 and corresponding row in the scan image. The controller 150 can then: analyze the scan image generated during the current scan cycle for capacitance values that indicate local compression of the elastic layer 140 by an object in contact with the touch sensor surface 142 and/or presence of a conductive object in contact with the touch sensor surface 142; and interpret these capacitance values as inputs on the touch sensor surface 142 accordingly.

In one implementation, the controller 150: compares each capacitance value in the scan image to a preset nominal capacitance value (e.g., a nominal capacitance, nominal charge time, or nominal discharge time) associated with the corresponding electrode pair in the capacitive touch sensor 120 or with all electrode pairs 122 in the capacitive touch sensor 120 generally; and correlates a capacitance value recorded in the scan image with an input at a corresponding location on the touch sensor surface 142 if the difference between the recorded capacitance value and the nominal capacitance value exceeds a threshold difference (e.g., a “threshold capacitance value perturbation”), as shown in FIG. 2. Alternatively, the controller 150 can: calculate an average (or other combination) of capacitance values recorded in the scan image; and correlate a capacitance value recorded in the scan image with an input at a corresponding location on the touch sensor surface 142 if the difference between the recorded capacitance value and the average capacitance value exceeds the threshold difference

### 5.1 Threshold Tuning

In one variation, charge durations, target charge voltages, and/or charge frequencies, etc. are executed by the controller 150 when charging electrodes 122 in the capacitive touch sensor 120 during a scan cycle such that electric fields projected by electrode pairs 122 through the elastic layer 140 exhibit a target strength or exhibit less than a threshold strength at the nominal plane (i.e., across the touch sensor surface 142 of the elastic layer 140 in the nominal state). The threshold capacitance value perturbation that the controller 150 implements to distinguish noise from an input on the touch sensor surface 142 can be matched to the target or threshold strength of these electric fields. In particular, the controller 150 can be preloaded with these drive and threshold values; alternatively, the controller 150 can tune these drive and threshold values throughout operation, such as based on capacitance values recorded from the capacitive touch sensor 120 during one or more preceding scan cycles.

For example, the controller 150 can drive electrodes 122 in the capacitive touch sensor 120 to induce an electric field exhibiting a particular strength at the nominal plane in the absence of a local force applied to the touch sensor surface 142. The controller 150 can also set the threshold capacitance value perturbation: that exceeds local perturbation of the electric field by an object (e.g., a typical conductive finger or non-conductive stylus) proximal the touch sensor surface 142 and offset above the nominal plane; and that is exceeded by local perturbation of the electric field by this object in contact with the touch sensor surface 142 and depressing a local region of the elastic layer 140 below the nominal plane.

By thus matching (or “tuning”) the threshold capacitance value perturbation to charging parameters for drive electrodes 122 in the capacitive touch sensor 120, capacitance values of electrode pairs 122 in the capacitive touch sensor 120 may vary (more) predominantly as a function of thickness of nearby regions of the elastic layer 140 than as a function of presence of an external object on order near the touch sensor surface 142, thereby enabling the controller 150 to detect both conductive and non-conductive objects on the touch sensor surface 142 and to distinguish intentional inputs on the touch sensor surface 142 from objects resting on or brushing across the surface.

However, charge parameters and the threshold capacitance value perturbation can be matched, tuned, or otherwise set in any other way and according to any other technique, such as preloaded into the controller 150 or calculated and adjusted by the controller 150 during operation of the system 100.

### 5.2 Capacitance Value: Discharge Time

In one implementation shown in FIG. 2, the controller 150 records discharge times of electrode pairs 122 in the capacitive touch sensor 120 during a scan cycle and detects inputs on the touch sensor surface 142 based on perturbations in these discharge times, such as from a nominal or average discharge time. In this implementation, local compression of the elastic layer 140—characterized by a dielectric constant (substantially) greater than the dielectric constant of air—can reduce capacitance between a nearby pair of electrodes 122 and thus decrease discharge time from a target high (“HI”) voltage to a target low (“LOW”) voltage, such as a function of compression distance of the nearby region of elastic layer 140. Furthermore, if the object in contact with this local region of the elastic layer 140 is conductive, presence of this conductive object near the capacitive touch sensor 120 can absorb electrical charge from these nearby electrode pairs 122, thereby further reducing discharge time of these electrode pairs 122 from the target high voltage to the target low voltage.

For example, the controller 150 can: sequentially charge (or “drive”) drive electrodes 122 in the array of drive electrodes 122 in the capacitive touch sensor 120 to a target high voltage; record discharge times—to a target low voltage—from corresponding sense electrodes 122 in the array of sense electrodes 122 in the capacitive touch sensor 120; and write these discharge times to a scan image for the current scan cycle. The controller 150 can also access a threshold discharge time difference preloaded into the controller 150 or calculated based on (e.g., as a fraction of) an average (or other combination) of discharge times of all electrode pairs 122 in the capacitive touch sensor 120 during one or more preceding scan cycles. The controller 150 can similarly access a nominal discharge time for electrode pairs 122 in the capacitive touch sensor 120 or calculate a nominal discharge time based on an average (or other combination) of discharge times of all electrode pairs 122 in the capacitive touch sensor 120 during one or more preceding scan cycles. The controller 150 can then detect an input at a particular location on the touch sensor surface 142 in response to a discharge time of a particular drive electrode—proximal the particular location—falling below the nominal discharge time by more than the threshold discharge time difference.

### 5.4 Elastic Layer Deformation

In another implementation as shown in FIG. 3, the elastic layer 140 is configured to: compress below the nominal plane at a first local region under an object depressed into the touch sensor surface 142 at the particular location; decrease capacitance between the particular sense electrode and the adjacent drive electrode as a function of compression of the elastic layer 140 at the first local region; expand above the nominal plane at a second local region adjacent the local region; and increase capacitance between a second sense electrode in the array of sense electrodes 122 and a second adjacent drive electrode in the array of drive electrodes 122 as a function of expansion of the elastic layer 140 at the second local region. In this implementation, the controller 150 is further configured to detect the object depressed into the touch sensor surface 142 at a particular location on the touch sensor surface 142 in response to decrease in capacitance between the particular sense electrode and the adjacent drive electrode and increase in capacitance between the second sense electrode and the second adjacent drive electrode.

Generally, in this implementation, the elastic layer 140 can be configured to both: locally compress (i.e., decrease in thickness) between the rigid substrate 110 and an object applied to the touch sensor surface 142; and locally expand (i.e., increase in thickness) adjacent the region of local compression as material from the region of local compression displaces laterally with depression of the object into the elastic layer 140. For example, the elastic layer 140 can exhibit a relatively low durometer (e.g., Shore 20) and relatively high elasticity in order to achieve such local deformation when an object is depressed into the touch sensor surface 142. When thus deformed, the region of local compression can thus yield reduced capacitance (and therefore shorter discharge times) at electrode pairs 122 immediately therebelow; conversely the region of local expansion can yield increased capacitance (and therefore longer discharge times) at electrode pairs 122 immediately therebelow.

In this implementation, the controller 150 can thus scan a scan image generated during a scan cycle for regions of reduced capacitance values (e.g., shortened discharge times) adjacent regions of increased capacitance values (e.g., lengthened discharge times) and confirm an input at the former region accordingly. In particular, the controller 150 can detect and confirm an input on the touch sensor surface 142 based on complementary changes in capacitance values in adjacent sets of electrode pairs 122.

### 5.5 Input Direction

In a similar implementation as shown in FIG. 3, the elastic layer 140 can selectively expand above the nominal plane ahead of an object moving across the touch sensor surface 142, whereas the elastic layer 140 gradually slopes back up the nominal plane behind the object as the object moves across the touch sensor surface 142. For example, in the foregoing implementation, the elastic layer 140 can expand above the nominal plane at the second local region ahead of the local region of compression as the object moves laterally across the touch sensor surface 142.

In this implementation, the controller 150 can: detect the object depressed into the touch sensor surface 142 at a first location on the touch sensor surface 142 in response to decrease in capacitance between a first sense electrode and corresponding drive electrode adjacent the first location; detect expansion of the elastic layer 140 above the nominal plane at a second location ahead of the object in response to increase in capacitance between a second sense electrode and corresponding drive electrode adjacent the second location; and confirm the input on the touch sensor surface 142 at the first location based on proximity of the second region of local expansion to the first region of local compression.

Furthermore, the controller 150 can calculate a direction of the object moving across the surface according to a position of the second location relative to the first location. For example, the controller 150 can: calculate a first centroid of the first local region of compression of the elastic layer 140; calculate a second centroid of the second local region of expansion of the elastic layer 140; calculate a direction of a vector spanning the first centroid and the second centroid; and store this direction as an approximate direction of the object moving across the touch sensor surface 142 during the current scan cycle. Upon receipt, a computing device can implement these input location and direction data to predict a future location of an object (e.g., a stylus) on the touch sensor surface 142 and thus reduce latency in detection and handling of inputs on the touch sensor surface 142 by the object.

The controller 150 can implement similar methods and techniques to detect orientation (or “tilt”) of an object, such as a stylus, depressed into the touch sensor surface 142 based on relative positions of adjacent compressed and expanded regions of the elastic layer 140.

### 5.6 Input Magnitude

In one variation as shown in FIG. 2, the controller 150 is further configured to: correlate a magnitude of reduction in capacitance, exceeding the threshold capacitance value perturbation, between the particular sense electrode and the adjacent drive electrode with a local change in thickness of the elastic layer 140 at the particular location; and transform the local change in thickness of the elastic layer 140 with a magnitude of a force applied to the touch sensor surface 142 at the particular location based on a known spring constant of the elastic layer 140.

In this variation, the controller 150 can transform deviation of a capacitance value between an electrode pair—from a nominal capacitance value, such as described above—with a change in thickness of the elastic layer 140 over this electrode pair, such as based on a predefined capacitance model. By then multiplying this change in thickness (i.e., a “compression distance”) of the elastic layer 140 over an electrode pair by a known spring constant of the elastic layer 140, the controller 150 can calculate a force applied to an area of the touch sensor surface 142 over this electrode pair. The controller 150 can also be loaded with a sense area of each electrode pair in the capacitive touch sensor 120, such as based on lateral and longitudinal pitch distances between electrode pairs 122 in the capacitive touch sensor 120, and can divide the calculated force applied to the touch sensor surface 142 over an electrode pair by the area associated with the electrode pair to calculate a pressure applied to this area of the touch sensor surface 142.

The controller 150 can: implement this process for each other electrode pair in the capacitive touch sensor 120 in order to estimate forces and/or pressure applied to corresponding areas of the touch sensor surface 142 during a current scan cycle.

### 5.7 Touch Image

Once the controller 150 has analyzed a scan image and interpreted deviations in capacitance values of electrode pairs 122 represented in the scan image as touch inputs on the touch sensor surface 142, the controller 150 can output touch data—such as lateral location, longitudinal location, input direction, and/or input magnitude (e.g., force or pressure), etc.—to a connected or integrated computing device, as shown in FIG. 3.

In one implementation, the controller 150: associates perturbations of capacitance value between contiguous electrode pairs 122 with one discrete input area; outputs coordinates of the centroid of this discrete input to the connected computing device; and repeats this process for each other discrete input area detected on the touch sensor surface 142 during the current scan cycle.

In another implementation, the controller 150 transforms the scan image into a touch image: containing null values (e.g., “0”) at locations corresponding to electrode pairs 122 for which changes in capacitance value (e.g., from a nominal capacitance value) remained below the threshold capacitance value perturbation; and containing non-null values (e.g., “1”) at locations corresponding to electrode pairs 122 for which changes in capacitance value exceeded the threshold capacitance value perturbation. In a similar implementation, the controller 150 can generate a touch image representing estimated forces or pressures on the touch sensor surface 142 over each electrode pair in the capacitive touch sensor 120. In these implementations, the controller 150 can also annotation the touch image with estimated directions of each discrete input, such as described above.

The controller 150 can thus generate a touch image based on capacitance value data collected during each scan cycle and output one touch image to a connected or integrated computing device per scan cycle throughout operation of the system 100.

However, the controller 150 can output touch input data—such as including location, direction, and/or magnitude of touch inputs on the touch sensor surface 142—in any other form or format.

### 6. Software Program

In one variation, the system 100 includes the elastic layer 140 configured to transiently install over an existing capacitive touch sensor 120 in a computing device, such as a capacitive touchscreen on a smartphone or tablet computer. In this variation, the elastic layer 140 can be paired with a software program 160 executable by the computing device (e.g., a controller 150 or capacitive touch sensor 120 in the computing device) to enable the computing device to detect inputs on the touch sensor surface 142 of the elastic layer 140 when the elastic layer 140 is installed on the computing device. For example, the software program 160 can function as a software update; when installed on the optical sensor of a computing device, the software program 160 can reconfigure (or “tune”) settings of the capacitive touch sensor 120 in the computing device to enable the computing device to detect inputs on the elastic layer 140 in light of the dielectric contrast, thickness, and elasticity of the elastic layer 140. In particular, in this variation, the software program 160 can be reconfigured by the computing device to implement methods and techniques described above to detect inputs on the touch sensor surface 142 of the elastic layer 140.

### 7. Conductive Particles

In one variation as shown in FIG. 3, the elastic layer 140 includes: a polymer film; and conductive particles 144 embedded in the elastic layer 140. For example, the elastic layer 140 can include a silicone substrate with aluminum, iron, or titanium, particles impregnated or cast into the silicone substrate.

In this variation, the conductive particles 144 in the elastic layer 140 can absorb charge from electrode pairs 122 in the touch sensor surface 142 and thus affect electric fields projected from electrodes 122 in the capacitive touch sensor 120. For example, conductive particles 144 in the elastic layer 140 can absorb electric charge from electrode pairs 122 in the capacitive touch sensor 120, thereby increasing charge time to a target high voltage and decreasing discharge time to a target low voltage generally. These conductive particles 144 may absorb electric charge at a rate proportional to proximity to the capacitive touch sensor 120. Thereby, when a local region of the elastic layer 140 is depressed by an object, this region of the elastic layer 140 may compress, thereby bringing conductive particles 144 in this region of the elastic layer 140 closer to adjacent electrode pairs 122 in the capacitive touch sensor 120. Decreased distance between conductive particles 144 in the region of the elastic layer 140 and adjacent electrode pairs 122 can further increase charge time to the target high voltage and further decrease discharge time to the target low voltage. The controller 150 can detect such capacitance value changes between electrode pairs 122 near this depressed region of the elastic layer 140 and interpret these capacitance value changes as an input at this location on the touch sensor surface 142 accordingly, such as according to methods and techniques described above.

The systems and methods described herein can be embodied and/or implemented at least in part as a machine configured to receive a computer-readable medium storing computer-readable instructions. The instructions can be executed by computer-executable components integrated with the application, applet, host, server, network, website, communication service, communication interface, hardware/firmware/software elements of a user computer or mobile device, wristband, smartphone, or any suitable combination thereof. Other system 100s and methods of the embodiment can be embodied and/or implemented at least in part as a machine configured to receive a computer-readable medium storing computer-readable instructions. The instructions can be executed by computer-executable components integrated by computer-executable components integrated with apparatuses and networks of the type described above. The computer-readable medium can be stored on any suitable computer readable media such as RAMs, ROMs, flash memory, EEPROMs, optical devices (CD or DVD), hard drives, floppy drives, or any suitable device. The computer-executable component can be a processor but any suitable dedicated hardware device can (alternatively or additionally) execute the instructions.

As a person skilled in the art will recognize from the previous detailed description and from the figures and claims, modifications and changes can be made to the embodiments of the invention without departing from the scope of this invention as defined in the following claims.

I claim:

1. A system for detecting inputs into a computing device comprising:
a rigid substrate;
a capacitive touch sensor arranged across the rigid substrate and comprising an array of electrodes;
an elastic layer:
arranged across the rigid substrate;
defining a touch sensor surface across a nominal plane offset above the rigid substrate; and
configured to locally deform inwardly toward the rigid substrate responsive to a local input applied to the touch sensor surface;
a controller configured to:
apply electrical voltage to electrodes in the capacitive touch sensor to induce an electric field projected through the elastic layer;
record capacitance values from electrodes in the capacitive touch sensor;
access a threshold capacitance value perturbation corresponding to presence of a conductive object below the nominal plane; and
detect an input at a particular location on the touch sensor surface in response to a local disturbance in capacitance value, read from a particular electrode in the set of electrodes in the capacitive touch sensor proximal the particular location, that exceeds the threshold capacitance value perturbation.

2. The system of claim 1:
wherein the rigid substrate and the capacitive touch sensor cooperate to define a touch-sensitive display; and
wherein the elastic layer comprises a translucent polymer film applied over the touch-sensitive display.

3. The system of claim 2:
wherein the rigid substrate comprises a silicate panel; and
wherein the elastic layer comprises a removable urethane layer transiently installed over the silicate panel.

4. The system of claim 1, wherein the elastic layer comprises:
a polymer film; and
conductive particles embedded in the elastic layer.

5. The system of claim 1:
wherein the rigid substrate defines a planar surface; and
wherein the elastic layer:
is arranged across the planar surface; and
defines the touch sensor surface across the nominal plane offset above the planar structure by a uniform offset distance, the touch sensor surface configured to locally deform below the nominal plane by a distance proportional to a magnitude of a local force applied to the touch sensor surface.

6. The system of claim 1, wherein the controller:
drives electrodes in the capacitive touch sensor to induce the electric field exhibiting a strength at the nominal plane in the absence of a local force applied to the touch sensor surface; and
sets the threshold capacitance value perturbation:
exceeding local perturbation of the electric field by an object proximal the touch sensor surface and offset above the nominal plane; and
exceeded by local perturbation of the electric field by the object in contact with the touch sensor surface and depressing a local region of the elastic layer below the nominal plane.

7. The system of claim 1:
wherein the array of electrodes in the capacitive touch sensor comprises an array of drive electrodes and an array of sense electrodes configured to capacitively couple to adjacent sense electrodes in the array of drive electrodes;
wherein the elastic layer:
is configured to reduce strength of the electric field between the array of sense electrodes and the array of drive electrodes across the nominal plane; and
is configured to decrease capacitance between a particular sense electrode in the array of sense electrodes and an adjacent drive electrode in the array of drive electrodes as a function of local depression of the touch sensor surface toward the rigid substrate proximal the particular sense electrode.

8. The system of claim 7, wherein the elastic layer is characterized by a dielectric constant greater than 3.0.

9. The system of claim 7, wherein the controller is configured to, during a scan cycle:
sequentially charge drive electrodes in the array of drive electrodes in the capacitive touch sensor to a target high voltage;
record capacitance values comprising discharge times to a target low voltage from sense electrodes in the array of sense electrodes in the capacitive touch sensor;
access the threshold capacitance value perturbation comprising a threshold discharge time difference; and
detect the input at the particular location on the touch sensor surface in response to a discharge time of the particular drive electrode, proximal the particular location, falling below a nominal discharge time by more than the threshold discharge time difference.

10. The system of claim 9, wherein the controller is configured to calculate the nominal discharge time based on a combination of discharge times of drive electrodes in the array of drive electrodes during a preceding scan cycle.

11. The system of claim 7, wherein the controller is configured to:
correlate a magnitude of reduction in capacitance, exceeding the threshold capacitance value perturbation, between the particular sense electrode and the adjacent drive electrode with a local change in thickness of the elastic layer at the particular location; and
transform the local change in thickness of the elastic layer with a magnitude of a force applied to the touch sensor surface at the particular location based on a known spring constant of the elastic layer.

12. The system of claim 11, wherein the controller is configured to output a lateral location, a longitudinal location, and the magnitude of the force applied to the touch sensor surface to the computing device.

13. The system of claim 7:
wherein the elastic layer is configured to:
compress below the nominal plane at a first local region under an object depressed into the touch sensor surface at the particular location;
decrease capacitance between the particular sense electrode and the adjacent drive electrode as a function of compression of the elastic layer at the first local region;
expand above the nominal plane at a second local region adjacent the local region; and
increase capacitance between a second sense electrode in the array of sense electrodes and a second adjacent drive electrode in the array of drive electrodes as a function of expansion of the elastic layer at the second local region;
wherein the controller is configured to detect the object depressed into the touch sensor surface at the particular location on the touch sensor surface in response to decrease in capacitance between the particular sense electrode and the adjacent drive electrode and increase in capacitance between the second sense electrode and the second adjacent drive electrode.

14. The system of claim 13:
wherein the elastic layer is configured to expand above the nominal plane at the second local region ahead of the local region as the object moves laterally across the touch sensor surface;
wherein the controller is configured to:
detect the object depressed into the touch sensor surface at the particular location on the touch sensor surface in response to decrease in capacitance between the particular sense electrode and the adjacent drive electrode
detect expansion of the elastic layer above the nominal plane at the second local region in response to increase in capacitance between the second sense electrode and the second adjacent drive electrode; and
calculate a direction of the object moving across the surface according to a position of the second local region relative to the first local region.

15. A system for detecting inputs into a computing device comprising:
a rigid substrate;
a capacitive touch sensor arranged across the rigid substrate and comprising an array of electrodes;
an elastic layer:
arranged across the rigid substrate; and
defining a touch sensor surface across a nominal plane offset above the rigid substrate; and
configured to locally deform inwardly toward the rigid substrate responsive to a local input applied to the touch sensor surface;
a controller configured to:
apply electrical voltage to electrodes in the capacitive touch sensor to induce an electric field projected through the elastic layer;
record capacitance values from electrodes in the capacitive touch sensor;
detect an input at a particular location on the touch sensor surface in response to a local disturbance in capacitance value read from a particular electrode in the set of electrodes in the capacitive touch sensor proximal the particular location.

16. The system of claim 15:
wherein the array of electrodes in the capacitive touch sensor comprises an array of drive electrodes and an array of sense electrodes configured to capacitively couple to adjacent sense electrodes in the array of drive electrodes;
wherein the elastic layer:
is configured to reduce strength of the electric field between the array of sense electrodes and the array of drive electrodes across the nominal plane; and
is configured to decrease capacitance between a particular sense electrode in the array of sense electrodes and an adjacent drive electrode in the array of drive electrodes as a function of local depression of the touch sensor surface toward the rigid substrate proximal the particular sense electrode.

17. The system of claim 16, wherein the elastic layer is characterized by a dielectric constant greater than 3.0.

18. The system of claim 16, wherein the controller is configured to, during a scan cycle:
sequentially charge drive electrodes in the array of drive electrodes in the capacitive touch sensor to a target high voltage;
record capacitance values comprising discharge times to a target low voltage from sense electrodes in the array of sense electrodes in the capacitive touch sensor;
access a threshold discharge time difference; and
detect the input at the particular location on the touch sensor surface in response to a discharge time of the particular drive electrode, proximal the particular location, falling below a nominal discharge time by more than the threshold discharge time difference.

19. A system for detecting inputs into a computing device comprising:
an elastic film:
configured to install over a capacitive touch sensor comprising a rigid substrate;
characterized by a dielectric constant greater than 3.0;
defining a touch sensor surface across a nominal plane offset from the rigid substrate;
configured to locally deform inwardly from the nominal plane toward the rigid substrate responsive to a local input applied to the touch sensor surface;
configured to reduce strength of an electric field projected by the capacitance touch sensor across the nominal plane;
configured to decrease capacitance between local pairs of electrodes in the capacitive touch sensor as a function of local depression of the touch sensor surface toward the rigid substrate proximal the particular sense electrode; and
configured to locally return the touch sensor surface to the nominal plane responsive to release of the local input from the touch sensor surface.

20. The system of claim 19, further comprising a software program executable by the capacitance touch sensor to detect an input at a particular location on the touch sensor surface in response to a local disturbance in capacitance read from a particular electrode in the capacitive touch sensor proximal the particular location.
